(19) United States
(12) Patent Application Publication
(10) Pub. No.: US 2025/0275294 A1
(43) Pub. Date: Aug. 28, 2025

(54) Quantum Photonic Energy Storage Cell and Manufacturing Methods Thereof

(71) Applicant: Hussein El-Ghoroury, Carlsbad, CA (US)

(72) Inventor: Hussein El-Ghoroury, Carlsbad, CA (US)

(21) Appl. No.: 19/206,804

(22) Filed: May 13, 2025

Related U.S. Application Data
(63) Continuation of application No. 18/223,482, filed on Jul. 18, 2023, now Pat. No. 12,324,270.
(60) Provisional application No. 63/390,165, filed on Jul. 18, 2022.

(51) Int. Cl. H10F 77/90; H10F 10/14; H10F 55/255; H10F 77/122; H10F 77/14; H10F 77/42

(52) U.S. Cl. CPC H10F 77/90; H10F 10/14; H10F 55/255; H10F 77/122; H10F 77/143; H10F 77/488

(57) ABSTRACT

An energy storage device comprising one or more solid state dielectric layers for use as a high-density electrical energy storage device.

### RELATED APPLICATIONS

This non-provisional utility patent application is a continuation of, and claims the benefit under 35 U.S.C. § 120, of U.S patent application. Ser.. No. 18/223,482, entitled “Quantum Photonic Energy Cell (QPEC)”, filed on Jul. 18, 2023, now allowed, which in turn claims the benefit under 35 U.S.C. § 119 (e) of U.S. Provisional Patent Application No. 63/390, 165, filed on Jul. 18, 2022, entitled “Quantum Photonic Energy Cell (QPEC)”, the entirety of each of which are incorporated herein by reference.

### FIELD OF THE INVENTION

The present invention relates to energy storage devices comprising multiple solid state dielectric layers to enable high density electrical energy storage.

### BACKGROUND

High density electrical energy storage devices are poised to become the next generation of energy storage devices to enable reduced dependance on fossil fuels and consequently reduce their adverse impact on the environment.

It is well known that despite recent progress in battery technology, the energy density gap between fossil fuels and current state of the art energy storage devices, such as Lithium-Ion batteries, is wide. As a result, the effort to reduce the use of fossil fuels is hampered by the wide gap in energy density between fossil fuels and current energy storage devices (herein referred to as the “energy density gap”). Any meaningful progress toward reduction on the dependance and demand for fossil fuels and a consequent reduction of their adverse impact on the environment must be focused on ways to reduce the wide energy density gap between fossil fuels and energy storage devices.

Several research and development efforts directed toward shrinking the energy density gap are ongoing. For example, there has been a continuing effort to improve the energy density of Lithium-Ion batteries, including Lithium-Ion super capacitors, Lithium-Air batteries, and solid-state capacitors, but unfortunately these efforts have not resulted in any meaningful increase the energy density of these energy storage devices nor has there been a material decrease in the energy density gap. Currently, the energy density of state-of-the-art energy storage devices is less than 5% of the energy density, both volumetric and gravimetric, of fossil fuels such as gasoline or JP-8. To make any significant impact in this field, existing energy storage device energy density must improve by at least one order of magnitude.

To achieve such an ambitious objective, different materials and different approaches for using such materials must be assessed and seriously considered for use in energy storage devices. Aside from energy density, a major consideration is of course cost. Any material considered for use in advanced energy storage devices must be both cost-effective, both in terms of raw material, as well the material's manufacturing costs, i.e., be cost-competitive using a similar cost metric of $/KW as with fossil fuels.

A common material that meets the above criteria is silicon (Si-14). It is well known that silicon is the one of the most abundant materials on Earth and is also one of the most well-understood and most widely manufactured materials on Planet. As a semiconductor, silicon has a relatively high dielectric constant of 11.9, making it an excellent candidate for energy storing capacitance applications. Due to silicon's low indirect bandgap energy of 1.12 eV, silicon is readily ionized by the full spectrum of light wavelengths greater than the infrared wavelengths, presenting an opportunity for a nonconventional method of ionization in energy storage applications.

In current energy storage devices, such as capacitors, the energy storing mechanism is typically polarization of the energy storage device core material. In both battery and super capacitor energy storage devices, the use of an electrolyte introduces ionization as the mechanism for storing energy. In most cases, the electrolyte used is either liquid or gel form. Undesirably though, in addition to added bulkiness, electrolytes introduce the added problem of potential leakage of the electrolyte from the device package.

In energy storage capacitors, the charge electric field provides the energy source that is converted into a polarization field for storage. In the case of devices that use ionization to store energy, including Lithium-Air batteries, the charge electric field provides the energy source that ionizes the core material for the storage of its energy.

It is noted that most directly ionizable materials, including lithium, have relatively low density, which represents a disadvantage in terms of their resultant energy density. Using silicon as an energy storage core material presents a significant advantage in terms of energy density since it is 4.36 times denser than lithium, having a relatively high atomic density of 5×10²² atom/cm³, beneficially offering high ion density when ionized.

The needed innovation is a practical approach to ionize silicon using a charge energy to create a robust and efficient energy storage device. Several advantages are offered by such an energy storage device:
(1) such a device offers an energy density that bridges the energy density gap between fossil fuel and current energy storage devices such as batteries and capacitors,
(2) when combined with state-of-the-art high energy density electric motors, the above combination offers overall system efficiency that is substantially higher than fossil fuels in combination with an internal combustion engine (ICE), as well that of lithium-ion batteries in combination with a high-density electric motor,
(3) such a device is safer to use than fossil fuels or lithium-ion because it is noncombustible,
(4) unlike lithium-ion batteries, such a device can be charged much quicker,
(5) such a device is more cost-effective than lithium-ion (7.6 Wh/$ or $132/KWh) and is competitive with fossil fuels cost using a $/KWh metric,
(6) such a device enables advances in wearable and mobile devices that are far more functionally capable than are currently available while being less bulky and operating much longer on a single charge,
(7) such a device defines a new horizon for electric vehicles in terms of range and operational efficiency,
(8) such a device ushers the era of electric aircraft, and,
(9) the above-described device beneficially assists in minimizing the current green-house gas emission problem and its devastating impact on the environment.

Additional objectives and advantages of embodiments of this invention will become apparent from the following detailed description of embodiments thereof that proceed with reference to the accompanying drawings.

### BRIEF DESCRIPTION OF THE DRAWINGS

The invention is illustrated by way of example, and not by way of limitation, in the figures of the accompanying drawings in which like reference numerals refer to similar elements.

FIG. 1A illustrates an exemplary cross-sectional view of the Quantum Photonic Energy Storage Cell (QPEC) of the invention according to a preferred embodiment.

FIG. 1B illustrates an expanded view of a contact layer 130 of an exemplary Quantum Photonic Energy Storage Cell (QPEC) according to a preferred embodiment of this invention.

FIG. 1C illustrates an expanded view of a contact layer 130 of an exemplary Quantum Photonic Energy Storage Cell (QPEC) according to a further preferred embodiment of this invention.

FIG. 2A illustrates the energy bandgap structure of the QPEC Si-Core material as a function of the wavevector k.

FIG. 2B illustrates the impact ionization process within the context of the energy bandgap structure of the QPEC 100 Si-Core layer 110 material of FIG. 2A.

FIG. 2C illustrates the avalanche ionization process that may be used to ionize the QPEC Si-Core material.

FIG. 2D illustrates the avalanche ionization chain reaction impact ionization created by the QPEC photo and electric field excitations.

FIG. 3 illustrates the 4-Fields balance of the QPEC according to a preferred embodiment of this invention.

FIG. 4 illustrates the various stages leading to the QPEC reaching the inversion state.

FIG. 5A illustrates the QPEC avalanche ionization process effect in creating the monolayer Si-Core separation of a few Si atoms in width.

FIG. 5B illustrates a formed ionized Si lattice divided into three regions, according to an alternative embodiment of the invention.

FIG. 6A illustrates the QPEC discharge configuration according to one embodiment of this invention.

FIG. 6B illustrates the QPEC discharge configuration according to another embodiment of this invention.

FIG.6C illustrates an embodiment of the QPEC 100 charge configuration.

FIG.6D illustrates an exemplary charge timeline of the QPEC 100.

FIG. 7 illustrates an exemplary packaging configuration of the QPEC of this invention.

FIG. 8 presents a comparison of the QPEC volumetric and gravimetric energy densities with that of popular batteries currently available and predicted to be available in the future.

### DETAILED DESCRIPTION OF THE INVENTION

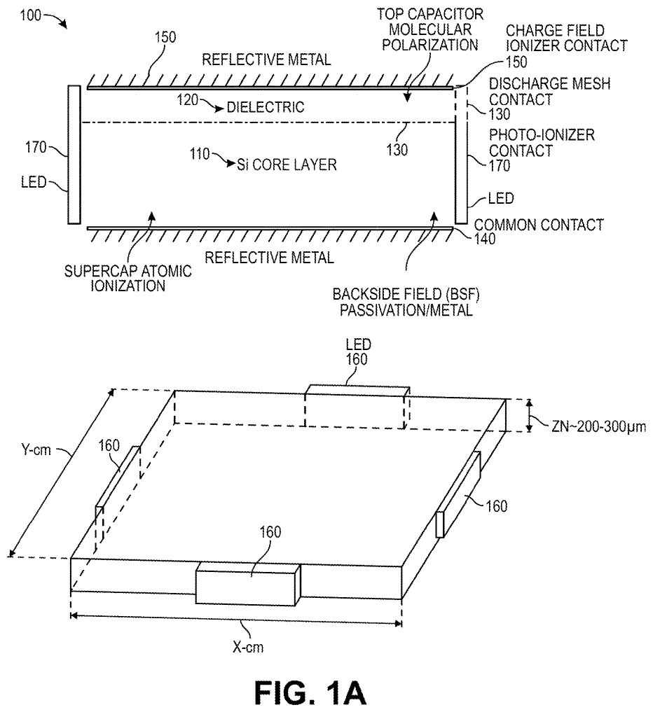

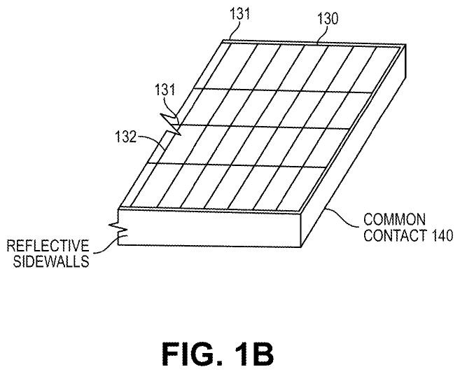

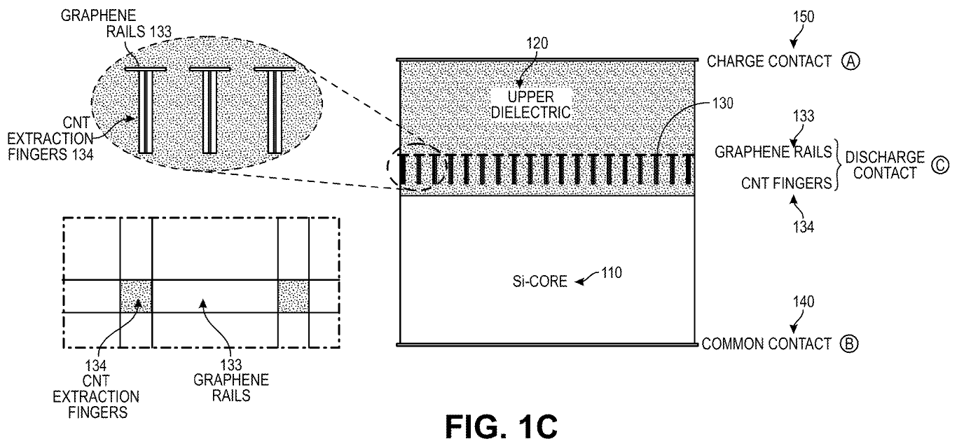

FIG. 1A illustrates an exemplary structure and preferred embodiment of the Quantum Photonic Energy Storage Cell 100 of the invention, referred to herein as the “QPEC”.

FIG. 1A illustrates a cross-sectional view of an exemplary structure of the QPEC 100. As illustrated in FIG. 1A, the QPEC is a multi-layer structure that comprises a core layer 110 preferably composed of monocrystalline Silicon (Si) of a thickness ranging from about 100 to 300 microns depending on the range of design requirements of the QPEC 100, as illustrated in the design example described below.

A thin cap layer 120 of highly crystalline wide band-gap dielectric material is deposited at one side or surface of Si-core layer 110. The thickness of cap layer 120, also referred to herein as the dielectric layer 120, is in the range of from about 20 to about 50 nanometers depending on the range of design requirements of the QPEC 100, as illustrated in the design example described below. The selected dielectric material for dielectric layer 120 preferably has a dielectric constant, designated as a, that is not higher than the dielectric constant of Si-core layer 110.

The selected dielectric material for dielectric layer 120 preferably has a band-gap energy, designated as Eg, that is higher (or wider) in energy than the band-gap energy of Si-core layer 110. An example dielectric material that meets both the dielectric constant a and band-gap energy Eg design criterion is Silicon Nitride (Si₃ N₄). The highly crystalline dielectric layer 120 is epitaxially deposited (grown) using either Atomic Layer Deposition (ALD) or Molecular Beam Epitaxy (MBA) deposition techniques at temperatures in a range of from about 100° C. to about 50020 C.

As illustrated in the cross-sectional view of FIG. 1A, a contact layer 130, for example, a buried mesh contact layer 130, is interposed at the interface between Si-core layer 110 and dielectric layer 120.

The isometric view of FIG. 1B provides an illustration of a preferred embodiment of contact layer 130 comprising metal rails 131 that are interconnected by thinner (less wide) metal fingers 132. The width of the metal contact rails 131 and fingers 132 may preferably range from about 50 to about 75 microns, respectively. The spacing between metal contact rails 131 of contact layer 130 may range from about 2-5 centimeters and the spacing between metal contact fingers 132 of contact layer 130 may range from about 2-5 millimeters. The metal of contact layer 130 rails 131 and fingers 132 may be selected from the group of metals that can be defused into Si-core layer 110 at high temperatures, such as Copper (Cu-29) or Silver (Ag-47).

Contact layer 130 rails 131 and fingers 132 are deposited on the top side or surface of Si-core layer 110 before dielectric layer 120 is deposited, using conventional semiconductor manufacturing methods of Silicon lithography, etching and metal deposition, then annealed at high temperature in the range from about 250° C. to about 600° C. to defuse the deposited contact layer 130 rails 131 and fingers 132 into the lattice of Si-Core layer 110 to a depth ranging from about 20 to about 50 microns.

The diffusion depth of deposited contact layer 130 rails 131 and fingers 132 into the lattice of Si-Core layer 110 creates a volume for contact layer 130 to extract the charge carriers from Si-Core layer 110. After the diffusion annealing step, the top side of deposited contact layer 130 is polished to a high planarity specification preferably of less than 0.5 nanometers, using high planarity semiconductor chemical mechanical polishing (CMP) techniques. High planarity polishing of deposited contact layer 130 is a desirable prerequisite for the subsequent deposition of highly crystalline dielectric layer 120.

In the alternative embodiment of the invention illustrated in FIG. 1C, contact layer 130 is realized using graphene rails 133 and Carbon Nano-Tube (CNT) fingers 134 extending therefrom, diffused into Si-Core layer 110.

Graphene is a single layer (monolayer) of carbon atoms, tightly bound in a hexagonal honeycomb lattice. As illustrated in FIG. 10, in this embodiment of contact layer 130, graphene rails 133 may be formed using lithographically patterned mono-or multiple layer graphene deposited using Chemical Vapor Deposition (CVD). Carbon nanotubes (CNT) fingers 134 may be formed using CVD, at high temperature in the range from about 500° C. to 80020 C., at the intersect points of graphene rails 133. CNT fingers 134 are diffused into Si-core layer 110 to a depth ranging from about 20 to about 50 microns to form the charge carrier extraction volume of contact layer 130.

Because of the electromagnetic transparency of graphene, graphene rails 133 may be formed as a continuous layer rather than as a mesh formed of intersecting rails. Because of their highly crystalline properties, the continuous graphene rails 133 embodiment of the invention serves as a deposition lattice surface for the highly crystalline dielectric layer 120.

According to this embodiment, graphene rails 133 are configured to transport the charge carriers collected by CNT fingers 134 to the extraction rails at the boundary of a graphene layer. The electromagnetic porous properties of graphene rails 133 and CNT fingers 134 allow the propagation of the electric field that is formed between the charge contact, i.e., contact layer 150, and the common contact, i.e., contact layer 140.

The relatively deep penetration of CNT fingers 134 into Si-Core layer 110 creates an extraction region or volume through which the charge carriers are transported by the de-screened upper region field (i.e., dielectric layer 120). The volume of charge carriers collected in the extraction region volume is defined by the penetration depth of the CNT fingers through Si-Core layer 110. The penetration depth of CNT fingers 134 into Si-Core layer 110 also defines the upper region field de-screening volume since the charge carriers that are extracted through CNT fingers 134 and graphene rails 133 create a de-screened field volume that extends across the penetration depth of CNT fingers 134 into the Si-Core layer 110. The layer of graphene rails 133 may comprise one or more monolayers of graphene as may be required by the charge carriers' extraction current and resistance.

In addition to contact layer 130, the QPEC structure illustrated in FIG. 1A may comprise two metal contact layers, both preferably Aluminum (AI), deposited on Si-Core layer 110 and dielectric layer 120 sides opposing the sides at which contact layer 130 is interposed at the interface of these two layers.

In FIG. 1A, the contact layer at the opposing Si-Core layer 110 surface is designated as contact layer 140 and the contact layer at the opposing dielectric layer 120 side is designated as contact layer 150. Within the operational context of the QPEC, contact layer 140 is used as a common contact while contact layer 150 is used to apply the QPEC charge potential in reference to common contact layer 140, and contact layer 130 is used to extract charge carriers from the QPEC at a potential in reference to common contact layer 140. Accordingly, contact layer 150 is designated as the “charge contact” and contact layer 130 is designated as the “discharge contact”, with both potentials in reference to common contact layer 140.

The QPEC is charged by the ionization and polarization effects of the combination of electric and photonic fields. Referring to FIG. 1A, the charge electric field is coupled onto the QPEC structure 100 across common contact layer 140, for the low potential side of the coupled electric field, and charge contact layer 150 for the high potential side of the coupled electric field.

As illustrated in FIG. 1A, the charge photonic field is generated by use of at least one, and preferably a plurality of photo-ionizing light emitting diodes (LEDs) 160 having their emissive apertures optically coupled to a lateral surface or edge of QPEC structure 100.

A fourth LED contact layer 170 of QPEC 100 is electrically coupled to a multiplicity of LEDs 160 to supply their drive potential in reference to common contact layer 140. The combined charge energy supplied to generate the electric field, coupled through contact layer 150, and to generate the photonic (light) field, coupled through LED contact layer 170, provides the total charge energy supplied to QPEC 100.

In one embodiment, contact layer 170 may comprise an optically reflective metal and the light pumped by photo-ionizing LEDs 160 is recycled by the reflective contact layers.

In an alternative embodiment, LEDs 160 transmit light in the blue range of 450 nm or shorter.

In a yet further embodiment, QPEC 100 has a width, x, in centimeters, a length, y, in centimeters, and a depth, z, in the range of 200-300 microns, wherein the values of x and y are selected to ensure uniform photo-ionization. Higher x and y values may require more LEDs coupled to one or more sides or lateral surfaces of QPEC 100.

The total charge energy supplied to QPEC 100 through the electric and photonic fields is stored as ionization energy in Si-Core layer 110 and as polarization energy in dielectric layer 120. These two stored energy components are electrically aligned, hence additive and combined, such that they balance the electric field energy coupled onto QPEC structure 100 through charge contact layer 150. At the initial stage of the charge process, the electric field coupled between common contact layer 140 and charge contact 150 polarizes both Si-Core layer 110 and dielectric layer 120. Simultaneous with this initial stage polarization, the photonic field optically coupled onto QPEC structure 100 ionizes Si-Core layer 110 through a photo-excitation process that excites electrons from the Si-Core layer 110 material valence energy band (VB) across the narrow indirect bandgap (1.12 eV) of Si-Core layer 110 material to its conduction energy band (CB).

The free photo-excited electrons are accelerated by the coupled electrical field, i.e., gain energy from the coupled electrical field, and scatter within the lattice of the Si-Core layer 110 material and excite additional electrons through a process known as “impact ionization”. As the photonic and electric field charge processes progress, more of the Si-Core layer 110 material atoms become excited and are physically separated by the coupled electrical field into negative ions (anion) that are transported toward the contact layer 130 region and positive ions (cation) that are transported toward the common contact layer 140 region.

Besides storing a portion of the energy charged onto QPEC structure 100, dielectric layer 120 electrically decouples (isolates) the free charge carriers that are coupled onto the (charge) contact metal (Al) layer 150 to create the charge electric field from the ionized Si-Core layer 110 while its formed dipolar polarization field acts to “transpose” the charge electric field potential coupled onto contact metal (Al) layer 150 to the interface between dielectric layer 120 and Si-Core layer 110.

In effect, dielectric layer 120 transposes the (charge) electric field coupled onto the contact metal (Al) layer 150 into a “stand-off” electrical field coupled onto the Si-Core layer 110 at the interface between the dielectric layer 120 and Si-Core layer 110, where contact layer 130 is physically located. The disclosed stand-off electrical field method of this embodiment provides energy storage capacitance while enabling the impact ionization effect on Si-Core layer 110 without interference from the free charge carriers that are coupled onto the charge contact metal (Al) layer 150 to create the charge electrical field potential.

Without the disclosed “stand-off” field method of this embodiment, it is not possible to couple the charge electrical field to realize the impact ionization effect into Si-Core layer 110. With the disclosed “stand-off” field method of this embodiment, the Si-Core layer 110 negative ions (anion) created by the combined effects of the electro-(impact) and photo-ionization processes are transported by the created stand-off field to contact layer 130 region, without interacting with the free charge carriers coupled onto charge contact metal (Al) layer 150.

Within the context of QPEC structure 100, the photonic excitation field coupled onto the QPEC structure 100 from the multiplicity of LEDs 160 selectively photo-ionize only Si-Core layer 110, but not dielectric layer 120, by first selecting the bandgap energy of dielectric layer 120 to be larger (or wider) than the minimum indirect bandgap energy of Si-Core layer 110 of 1.12 eV and second by the selecting the photonic field photons energy, which is empirically valued as Eₚ(eV)=_{Photons Wavelength(nm)}¹²⁴⁰, to be greater than the Si-Core layer 110 material indirect bandgap energy of 1.12 eV and selected to be as close as possible in value to the Si-Core layer 110 material direct bandgap energy of 3.4 eV.

With these design selection criteria, the coupled photonic field is only absorbed by the Si-Core layer 110 material and photo-excites its electrons to an energy level sufficient to excite other electrons by impact ionization after being accelerated by the coupled stand-off electric field to greater than twice the value of the minimum indirect bandgap energy of the Si-Core layer 110. The stated design criteria in this embodiment for selective photo-ionization of Si-Core layer 110 requires the photonic field photons' energy to be in the range from 2.24 eV to 3.4 eV, with an associated wavelength in the range from 365 nm (UV) to 554 nm (G). In the design examples disclosed hereinbelow, the selected photo-ionization field photons' energy is 2.75 eV with an associated wavelength of 450 nm, for which LED material is commercially widely available at cost-effective prices, which is another pertinent design criterion of the QPEC 100.

The term “polarization” is used herein to indicate the alignment of charges with the electric field coupled onto QPEC structure 100 through the two metal contact layers 140 and 150. In the case of the material of the dielectric layer 120, the coupled electric field causes deformations of the atomic (electrons) orbitals of the material, which partially de-screens the positive electric charges of the atomic nucleus and creates charge dipoles. In this process, the electrons of the dielectric layer 120 material remain in their bound orbitals with their energy levels within the valence band (VB).

The term “polarization” in this case is meant to indicate the alignment of the formed dipoles with a coupled electric field and are referred to herein as “dipolar polarization”. However, the maintained bound state of the dielectric layer 120 material electrons prevents the interaction between the formed dipoles and the free charges of metal contact layer 150—an effect that causes the electric field coupled onto QPEC structure 100 to be a stand-off field relative to dielectric layer 120. The opposing electric field created by dielectric layer 120 dipolar polarization transposes the high potential side of the electric field coupled onto QPEC structure 100 through metal contact layer 150 to the interface between dielectric layer 120 and Si-Core layer 110 at contact layer 130 region while maintaining electrical isolation between the metal contact layer 150 free electrons and contact layer 130. This design aspect of QPEC 100 extends the electric field coupled into QPEC structure 100 through the two metal contact layers 140 and 150 to also become a stand-off electric field relative to Si-Core layer 110.

In the case of the material of Si-Core layer 110, the combined impact ionization and photonic ionization effects of the transposed electric field and the coupled photonic field, respectively, cause the fields' excited electrons to transfer from the Si-Core layer 110 material valence band (VB) to its conduction band (CB) and to become “free” electrons that can be physically transported, within the conduction band (CB), across the lattice of the Si-Core layer 110 material. In this case, an added effect of the coupled stand-off electric field is that the excited free electrons are also driven (or transported) by the coupled stand-off electric field towards the transposed high potential side of the field at the dielectric interface where contact layer 130 is located.

The transport process of the excited free electrons by the transposed electric field causes the Si-Core layer 110 atoms near the contact layer 130 region to accept the transported free electrons in their conduction band (CB), thus forming negative ions (or anions), while leaving behind the Si-Core layer 110 atoms missing the excited electrons, which form positive ions (or cations), concentrated in the common contact layer 140 region. The term “polarization” in this case is meant to indicate the transport of the formed Si-Core layer 110 ions and separation to the respective regions of the coupled stand-off electric field near contact layer 130 and common contact layer 140, respectively, and this process is referred herein as “ionic polarization”.

The ionic polarization process used in QPEC 100 is vastly different than the process used in the most popular battery, the lithium-ion battery, where anions (electrons) are fixed at the anode region while the much larger portion of the ionized lithium atoms that form the cations are transported, through a gel or liquid electrolyte, to the cathode region of the battery. As is well known, transporting the larger sized ions during the ionic polarization of the lithium-ion battery represents its major weakness in that it causes strain on the battery core material and results in a subsequent adverse lifecycle impact on battery performance.

By comparison, in the ionic polarization process of QPEC 100, the free electrons, which are much lighter and smaller than the silicon atoms, are transported across the Si-Core layer 110 lattice atoms without the need for an electrolyte.

As a result of the QPEC 100 ionic polarization process, the formed Si-Core layer 110 ions are separated by the transposed stand-off electric field coupled onto the metal contact layers 140 and 150 to become electrically opposing and thus balancing the stand-off electric field with the negative ions (anions) at the side of the Si-Core layer 110 facing the dielectric layer 120, the contact layer 130 side, and the positive ions (cations) at the common contact layer 140 side. As the ionic polarization of the Si-Core layer 110 progresses during the charge process, a capacitance is formed by Si-Core layer 110 un-ionized atoms separating the positive and negative ions of Si-Core layer 110. The formed Si-Core layer 110 capacitance is configured electrically in parallel with the dielectric layer 120 capacitance, hence their polarization fields are opposing, and their respective capacitance is additive. Furthermore, the electrical balancing aspects of the formed Si-Core layer 110 and the dielectric layer 120 capacitance make the electrical energy stored in each of these two capacitances substantially equal.

Thus, the QPEC charging mechanism comprises the following characteristics:
(1) Photo-ionizer LEDs 160 photoexcite charge carriers in the Si-Core layer 110;
(2) The electric field energizes the photoexcited charge carriers;
(3) The energized charge carriers excite more charge carriers by impact ionization (self-quenched avalanche effect);
(4) The combined photo plus electric field ionizations charge the Si-Core layer 110 capacitance to the molecular level;
(5) Dielectric layer 120 is charged by dipolar polarization as charge carriers accumulate at the discharge contact, i.e., the contact layer 130; and;

Si-Core layer 110 and dielectric layer 120 capacitance are charged in opposite directions relative to common contact layer 140.

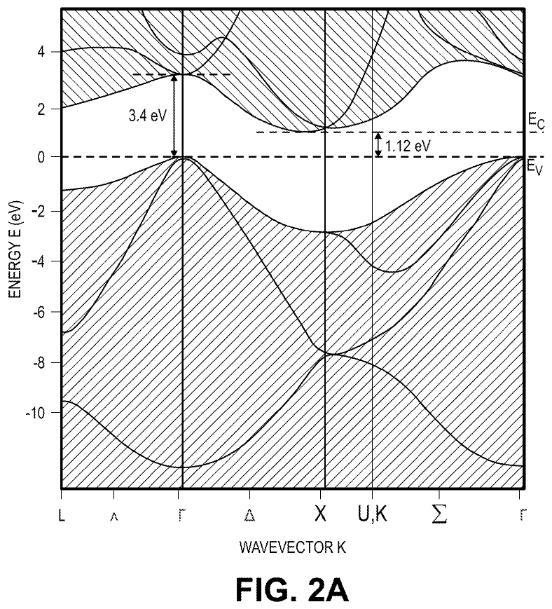

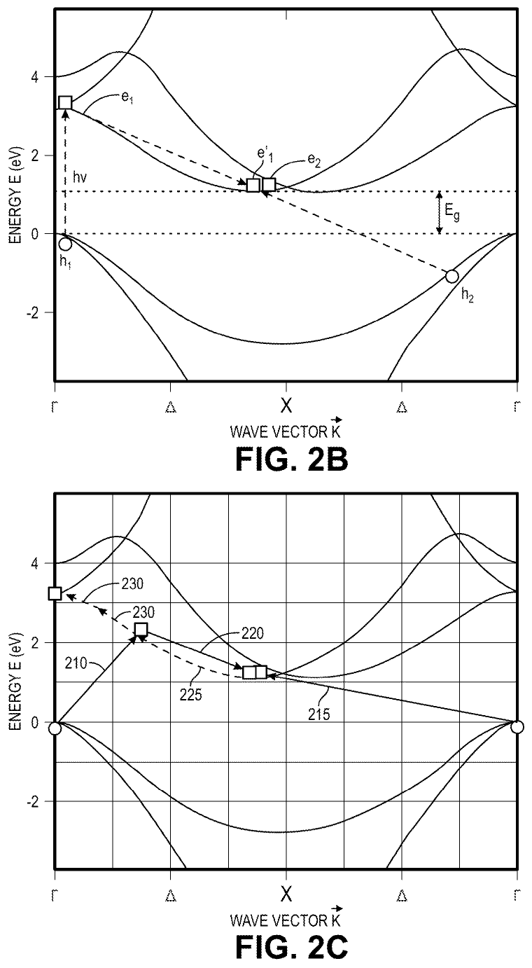

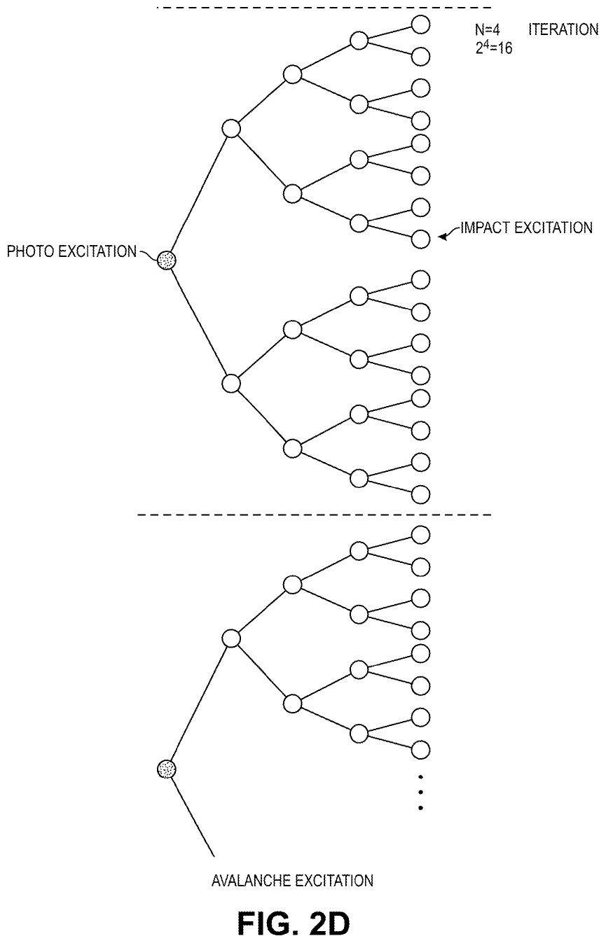

FIG. 2A illustrates the energy bandgap structure of the QPEC 100 Si-Core layer 110 material as a function of the wavevector k. As illustrated in FIG. 2A, the QPEC 100 Si-Core layer 110 material has a 1.12 eV indirect bandgap separating the valence band (VB) maximum energy level, along the I′ symmetry point, and conduction band (CB) minimum energy level, along the X symmetry point. The QPEC 100 Si-Core layer 110 material also has a 3.4 eV direct bandgap separating the valence band (VB) and conduction band (CB) maximum energy levels, along the I symmetry point.

The S-shape of the QPEC 100 Si-Core layer 110 material energy band structure, as described below, affects the impact ionization process. The impact ionization process involves electron scattering within the Si material lattice. Electron scattering within the SI material lattice involves the exchange of potential energy as well as momentum that enables the excited electrons to transition along both the energy E (eV) axis as well as the wavevector k axis. The photo-excitation of the QPEC 100 Si-Core layer 110 material by the light emission from the multiplicity the photo-ionization LEDs 160 excites electrons from the VB to the CB across the minimum indirect bandgap, a process which also involves phonons scattering (lattice) to provide the needed momentum that enables the transition along the wavevector axis k needed to cross the indirect bandgap.

The described QPEC 100 Si-Core layer 110 ionic polarization process also provides an added mechanism, besides the phonon scattering, for excited electron scattering that enables electron excitation across the Si-Core layer 110 material indirect bandgap. The described QPEC 100 Si-Core layer 110 ionic polarization process provides a mechanism for excited electrons of the QPEC 100 Si-Core layer 110 material to be accelerated while being transported by a stand-off field effect and gain potential energy to transition across the energy axis of the energy bandgap structure of FIG. 2A. With these two mechanisms of excited electron scatterings, the excited electrons undergo an ionization induced by an electron-lattice scattering process, known as “impact ionization”.

FIG. 2B illustrates the impact ionization process within the context of the energy bandgap structure of the QPEC 100 Si-Core layer 110 material of FIG. 2A. FIG. 2B illustrates an excited electron ei that has potential energy in excess of twice the indirect bandgap energy (2E_{g}=2.24 eV), gained either by photo-excitation, the stand-off field effects described above or their combination, undergoing an impact ionization process during which the excited electron ei gives up its excess energy above twice the indirect bandgap energy (2E_{g}=2.24 eV) to excite another electron e2 across the indirect bandgap energy E_{g}.

With the described stand-off field effects, both the excited electrons ei and e2 gain energy from the stand-off field and subsequently undergo another cycle of impact ionization process with each exciting an additional electron. This impact ionization chain reaction effect is known as “avalanche ionization”, a process to which semiconductor material breakdown is attributed when the energy gained by the excited electrons from an electric field approaches the material's first ionization energy level.

For Si material, the first ionization energy is 8.4 eV and inducing avalanche ionization by an electric field effect alone would require an applied field potential that approaches the Si material breakdown field potential of 30 V per micron.

FIG. 2C illustrates the avalanche ionization process used to ionize the QPEC 100 Si-Core layer 110 material. Referring to FIG. 2C, the exemplary avalanche ionization process used to ionize the QPEC 100 Si-Core layer 110 material is seeded or induced by photonic excitation 210 generated by the optically coupled light emitted from the LEDs 160 having photons' energy hu greater than twice the indirect bandgap energy (2E_{g}=2.24 eV). The photoexcited electrons scatter within the Si-Core layer 110 material lattice, undergo the described impact ionization process of FIG. 2B, excite other electrons 215 across the Si-Core layer 110 material indirect bandgap to the conduction band minimum, then relax 220 to the conduction band minimum near the X symmetry point.

The electrons generated by the impact ionization process gain energy 225 from the stand-off electric field, coupled through the metal contact layers 140 and 150, to reach the QPEC 100 Si-Core layer 110 material conduction band (CB) maximum across the Si-Core layer 110 material direct bandgap of 3.4 eV at the I′ symmetry point, then undergo another cycle of impact ionization creating the avalanche ionization chain reaction illustrated in FIG. 2D.

Similarly, the holes created by the avalanche ionization process in the valence band (VB) gain energy 230 from the coupled stand-off field to reach the QPEC 100 Si-Core layer 110 material valence band (VB) maximum across the Si-Core layer 110 material direct bandgap of 3.4 eV.

As illustrated in FIG. 2C, since both potential energy and momentum are conserved during the process, the holes created by the avalanche ionization process in the valence band (VB) are located at the VB maximum when the impact ionization that generated the holes was initiated by electrons with a potential energy that exceeds nearly twice the indirect bandgap energy (2E_{g}=2.24 eV). As the ionization density of the Si-Core 110 material increases by the impact ionization process, fewer un-ionized Si-Core 110 atoms become available for the excited electrons to scatter with, and the excited electrons 230 continue to gain potential energy from the coupled field to reach the QPEC 100 Si-Core 110 material conduction band (CB) maximum across the Si-Core 110 material direct bandgap of 3.4 eV at the I′ symmetry across from the holes accumulated at VB maximum. As the avalanche process continues, the exited electrons and holes accumulate across the Si-Core layer 110 material direct bandgap of 3.4 eV in their respective energy band maxima.

The foregoing explanation describes the ionic polarization process that results from the avalanche ionization process of the QPEC 100 in the wavevector k energy space. The electrons and holes generated by the avalanche process are physically separated and transported across their respective sides of the stand-off electric field, coupled through the metal contact layers 140 and 150 of the QPEC 100 Si-Core layer 110 material, to form positive and negative ions, cations and anions, respectively.

In effect, the avalanche ionization process of QPEC 100 creates Si-Core layer 110 ions that are electrically aligned in an opposing direction of the coupled stand-off electric field, physically separated to their respective sides of the Si-Core layer 110 material, i.e., ionically polarized, and having 3.4 eV of potential separation that constitutes the created Si-Core layer 110 ions' chemical potential, since the ions are aligned in the wavevector k energy space across the Si-Core layer 110 direct bandgap of 3.4 eV.

Besides the prerequisite that the photo-excitation light generated by the LEDs 160 have a potential energy Eₚ=hυ in excess of twice the value of the Si-Core layer 110 indirect bandgap of E_{g}=1.12 eV, i.e., Eₚ=hυ>2.24 eV, the avalanche ionization process of QPEC 100 requires the stand-off field coupled through the metal contact layers 140 and 150 of the QPEC 100 to enable an impact ionization process that further excites the electrons in the Si-Core layer 110 material CB to: (1) a potential energy in excess of twice the value of the Si-Core layer 110 indirect bandgap of E_{g}=1.12 eV, i.e., Eₑ>2.24 eV, and, (2) a momentum wavevector k aligned along the axis extending from the I′ to the X points, i.e., directed along the (100) Miller coordinates of the Si-Core layer 110 crystalline material, where the conduction band (CB) minimum of the Si-Core layer 110 material is located (see FIG. 2C).

Both conditions are met when the stand-off field electric field, coupled through the metal contact layers 140 and 150 of the QPEC 100 Si-Core layer 110 material, is aligned along the QPEC Si-Core layer 110 material X-axis and having the potential energy sufficient to increase the potential energy of the excited electrons to reach the impact ionization threshold of E_{f}>2.24 eV per excited electron.

In effect, the electrons excited by the avalanche ionization process of QPEC 100 integrate the potential energy from the stand-off field electric field, coupled through the metal contact layers 140 and 150 of the QPEC 100, while being transported by the field along the X-axis of the Si-Core layer 110 crystalline material to reach the impact ionization threshold, while simultaneously their momentum is being aligned in the direction where the excited electrons relax, i.e., the selected direction of the coupled the stand-off field electric field.

QPEC 100 Quantum Ionization Effect—the foregoing description discloses the details of the photonic and stand-off electric fields induced avalanche ionization process of the QPEC 100. Unlike an impact ionization process induced by only a photonic field excitation of FIG. 2B or that is induced only by an electric field excitation, in the photonic/electric fields-induced avalanche ionization process of the QPEC 100, the excitation occurs in quanta of E_{g}.

The net effect of the QPEC 100 avalanche ionization process is that the maximum direct bandgap energy Eₘₐₓ of Si-Core layer 110 is quantized by the coupled stand-off electric field into quanta that equals the minimum indirect bandgap energy E_{g}. As described earlier, in the QPEC 100 avalanche ionization process, excited free electrons (and holes) gain (and integrate) potential energy and momentum while being transported by the coupled electric field.

When the integrated potential energy of the excited electron reaches 2Eg, the electron undergoes a quantum energy transfer process in which it emits a photon of potential energy E_{g}; its excess energy above the CB minimum energy. The photon is absorbed by a lattice-bound electron of an adjacent un-excited Si atom, causing that electron to be excited across the minimum indirect bandgap energy Eg, hence the excited electron multiplication effect of the avalanche process. In this process, both excited electrons gain momentum; the newly excited electron gains momentum to cross the indirect bandgap and reaches the CB minimum and the relaxed electron gains momentum in the direction of the coupled stand-off field to resume its transport across coupled field and resets the process of integrating potential energy from the coupled stand-off field. The process is repeated when the integrated potential energy of both excited electrons reaches 2E_{g}. As this quantized relaxation, excitation (multiplication) and transport process continues, fewer adjacent un-excited atoms become available in the vicinity of the electrons transported by the coupled stand-off field and approaching the high potential side of the coupled field.

As a result, the potential energy integration effect exhibited by the excited electrons continues beyond 2E_{g} to reach 3E_{g} towards the Si VB maximum energy point where the excited electron stops gaining momentum and settles at the Γ point where k=0 and its potential energy gain becomes restricted by the Si energy band structure.

This process, in effect, tightly packs the excited electrons within the region of Si atoms adjacent the high potential side of the coupled electric field where the excited electrons, thus the negative Si ions are settled at the Si CB maximum energy point, and the top of the direct Si energy bandgap and the resultant holes, thus the positive Si ions, are tightly packed within the region of Si atoms adjacent the low potential side of the coupled electric field.

The holes generated by the described quantized relaxation process are generated at the Si VB maximum energy at the I point where k=0 since when the excited electron integrated potential energy is reset at the point it reaches 2E_{g}, the electron's integrated potential energy and momentum is partitioned equally between the process's two excited electrons, settling at the CB minimum at X symmetry point, thus creating a hole at the ground state of the Si VB maximum at the I point where k=0. In effect, therefore, the described Quantum Ionization Effect of the QPEC 100 amplifies the photonic/electric fields-induced avalanche ionization process while integrating the resultant electrons and holes across the Si maximum energy bandgap, in the k-space energy band structure, and physically across the opposing sides of the coupled electric field. This is a unique process dominated by electron/lattice quantized energy interaction (or scattering) which suppresses the undesirable electron/phonon interaction (or scattering) that tends to cause scattering electron energy transfer inefficiencies.

As the electrons and holes that are excited by the avalanche ionization process gain potential energy from the coupled field, they are also transported to their respective sides of the coupled field, i.e., electrons are transported toward the contact layer 130 and holes are transported toward the common contact layer 140. As the avalanche ionization process continues, the Si-Core layer 110 is partitioned into three regions, namely, a region of negative ions near the contact layer 130 and a region of positive ions near the common contact layer 140 separated by a region of un-ionized Si-Core layer 110 atoms.

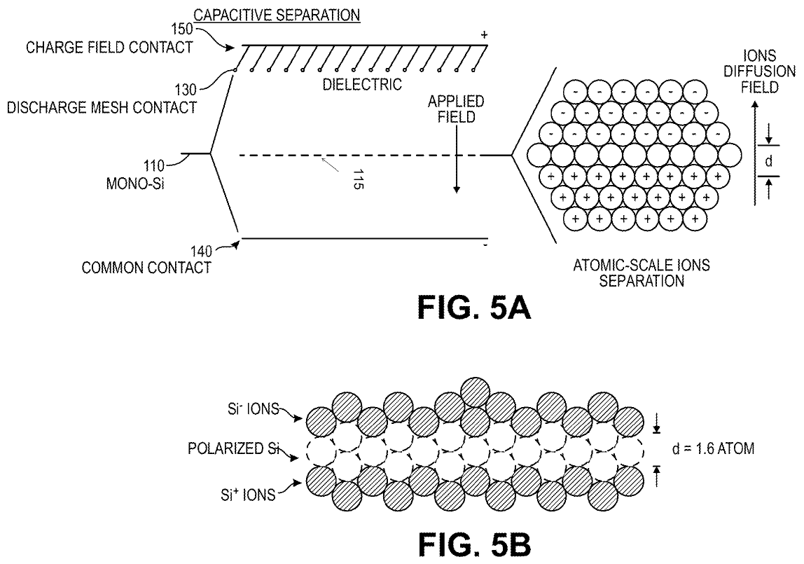

As the avalanche ionization process continues, the un-ionized region of the Si-Core layer 110 forms a Si-Core layer 110 capacitance, illustrated by the dashed line 115 in FIG. 5A, that separates the ionized Si-Core layer 110 regions. The formed dipolar polarization field of the formed Si-Core layer 110 separation capacitance is electrically aligned with the coupled stand-off field and acts to strengthen the ions' separation action of the coupled stand-off field. As the avalanche ionization process continues, the width of the formed Si-Core layer 110 ions' separation region systematically decreases as the widths of the opposing negative and positive ions' regions systematically increase. As a result, the formed Si-Core layer 110 capacitance 115 increases systematically with the progression of the avalanche ionization process.

4-Fields' Balance—during the avalanche ionization progression, four electric fields (4-Fields) are electrically in balance in one direction, the coupled electric field is electrically aligned, thus additive, with the dipolar polarization field of the Si-Core layer 110 capacitance 115, and in the opposite direction, the Si-Core layer 110 ions field is electrically aligned, thus additive, with the dipolar polarization field of the dielectric layer 120.

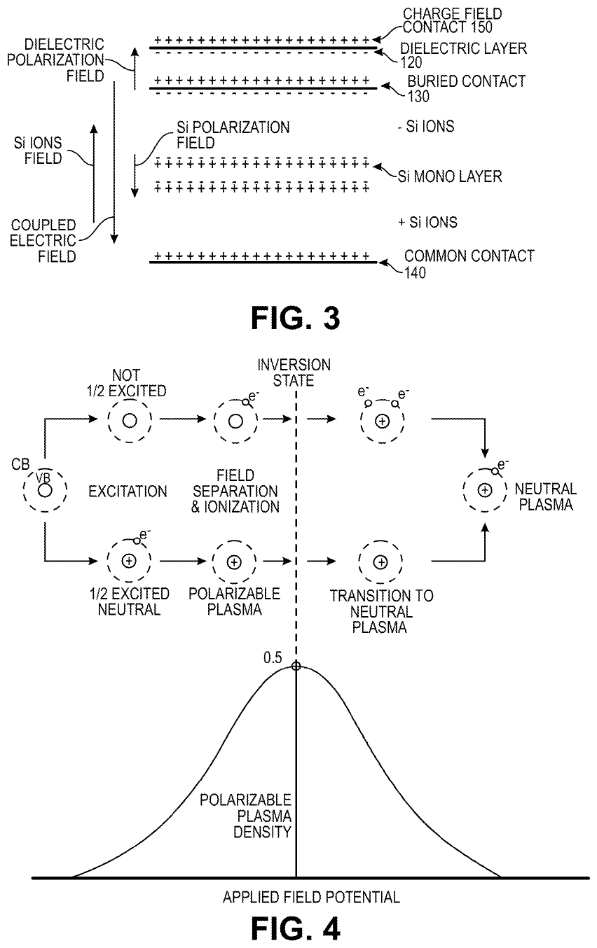

FIG. 3 illustrates the 4-Fields' balance of the QPEC 100. When the avalanche ionization process drives the QPEC 100 to the fully charged state, the electrical balance of these 4-Fields makes the energy stored in the Si-Core layer 110 capacitance separation 115 equal to the energy stored in the dielectric layer 120 capacitance and since the Si-Core layer 110 separation capacitance 115 and the dielectric layer 120 capacitance are aligned in parallel, the energies stored in the Si-Core layer 110 and the dielectric layer 120 are additive.

Inversion State—with the described 4-Fields' balance of the QPEC 100, the Si-Core layer 110 separation capacitance 115 dipolar polarization field reinforces the Si-Core layer 110 ions' separation action of the coupled stand-off electric field internally from the center of the Si-Core layer 110. The Si-Core layer 110 separation capacitance 115 dipolar polarization field becomes stronger as the Si-Core layer 110 separation 115 width is decreased by the avalanche ionization and ions' separation action of the coupled stand-off electric field. When the coupled stand-off field is made stronger, at a higher potential coupled between the QPEC 100 contact layers 140 and 150, its avalanche ionization and separation action increases, and consequently the Si-Core layer 110 separation capacitance 115 width decreases and its dipolar polarization field strength increases, further reinforcing the Si-Core layer 110 ions' separation action of the coupled stand-off field. Reciprocally, the coupled stand-off electric field, being opposed to the Si-Core layer 110 ions' field, screens the Si-Core layer 110 ions' potential separation as the Si-Core layer 110 separation capacitance 115 width decreases.

An action that allows the Si-Core layer 110 ions' separation capacitance 115 width to be reduced to the order of few Si atoms, i.e., few hundred picometers, width without reaching breakdown condition due to the Si-Core layer 110 ions' potential separation. With the Si-Core layer 110 ions' potential separation screening action of the coupled stand-off field, the limit of the stand-off field potential increase is set forth by the dielectric layer 120 capacitance that is responsible for transposing the electric field coupled through the QPEC 100 contact layers 140 and 150 to the Si-Core layer 110 interface. This limit is determined by the breakdown potential of the dielectric layer 120.

When the dielectric layer 120 design parameters, i.e., dielectric constant and thickness, are selected to enable the coupled stand-off field induced avalanche ionization and separation to excite nearly half of the Si-Core layer 110 atoms and separate the formed ions to their respective sides, the achieved Si-Core layer 110 ion density approaches the Si-Core layer 110 material atomic density, i.e., ˜5×10²² ions per cm³. This state is herein referred to as the “inversion state” and it defines the fully charged state of the QPEC 100.

FIG. 4 illustrates the various stages leading to the QPEC 100 reaching the inversion state. As illustrated in FIG. 4, when the Si-Core layer 110 atoms are excited by the combined action of the coupled photo and electric fields, the Si-Core layer 110 atoms are first ionized, then the resultant excited electrons are transported by the coupled electric field to the high potential side of the coupled field leaving behind the unexcited Si-Core layer 110 atoms that have accumulated at the low potential side of the coupled field. As this process of Si-Core layer 110 atom excitation and separation continues, the excited electrons are separated from their excited atoms, leaving behind a positive ion atom at the low potential side of the coupled field and the separated excited free electrons become predominantly located within the CB of the unexcited Si-Core layer 110 atoms, thus accumulating negative ions atoms at the high potential side of the coupled field.

As illustrated in FIG. 4, this process leads to the formation of negative and positive Si ion plasma that is polarized to the opposing sides of the coupled field. The formed polarized Si ions' plasma density systematically increases as the process continues until nearly one half of the Si-Core layer 110 atoms are excited, at which point the Si ions are separated by a monolayer layer of unexcited Si atoms that are separating the polarized Si ions plasma sides. At this stage, the Si ions' plasma density reaches its maximum value.

As illustrated in FIG. 4, when the Si-Core layer 110 ionization continues further to tip the polarized Si ions' plasma balance achieved at the inversion state, fewer unexcited Si atoms are available to form negative Si ions and at that stage the formed Si plasma is gradually transferred into un-polarizable neutral plasma. Since continuing the photo and electric fields ionization action beyond the inversion state transitions the formed Si ions into un-polarizable neutral plasma, the maximum polarizable Si ions' plasma density occurs when the inversion state is reached. Therefore, the QPEC 100 is fully charged when the inversion state is reached.

Monolayer Si-Core Layer 110 Separation—when the inversion state is reached, the described ions' separation action of the QPEC 100 avalanche ionization process ionizes the Si-Core layer 110 and transports (polarizes) the Si ions towards their respective sides of the coupled electric field, leaving a monolayer of un-excited and un-ionized atoms closely packed at the center of the Si-Core layer 110 separating the opposing Si ions that have accumulated at the opposing sides of the coupled electric field.

FIG. 5A illustrates the QPEC 100 avalanche ionization process effect in creating the monolayer Si-Core layer 110 separation of a few Si atoms in width. As earlier stated, the 4-Field balance effect causes screening of the Si ions' chemical potential, i.e., the potential separation across the Si-Core layer 110 material maximum direct bandgap energy Eₘₐₓ=3.4 eV. As a result of the Si ions' chemical potential screening, the monolayer Si-Core layer 110 separation can reach a few Si atoms in width. Given the Si covalent diameter of 220 pm, the closely packed monolayer Si-Core layer 110 of 2, 3, and 4 Si atoms' width creates approximately 380 pm, 572 pm, and 760 pm of Si ion separation, respectively. These width values of the monolayer Si-Core layer 110 separation and the fact that the formed Si-Core layer 110 capacitance value increases with the increase of the coupled stand-off field potential make the formed Si-Core layer 110 separation capacitance a “Super Capacitance”.

Again with reference to FIG. 5A, with seed photo-excitation, the applied field potential: 1) excites the mono-Si atoms by impact excitation, 2) relaxes the excited charge carriers of the mono-Si atoms to the edges of the Si band-gap energy, and in this process, 3) converts the excited charge carriers' energy in excess of the Si band-gap energy into additional carriers (avalanche magnification effect), then, 4) transports, the Si ions toward the opposing sides of the mono-Si. Also, as explained, this excitation/ionization/polarization process continues until it “self-quenches” at the point when the diffusion field of the separated Si ions is in opposing balance with the applied field, a condition that defines the “fully charged” state of the formed Si capacitance.

The energy stored within the formed Si capacitance depends on the magnitude of the applied field potential, or density, the higher the applied field potential, the higher the Si ionic concentration within the formed Si capacitance. This is because the increased applied field potential contributes to increasing the ionic density (or number of generated Si ions), a property not shared by dielectric or electrolytic capacitance. The ions' separation effect by the applied field potential systematically separates the opposing charge ions to correspondingly opposing sides of the mono-Si. (See FIG. 5A). As a result, the formed ionized Si lattice is divided into three regions: 1) a positive ion region at the side of the opposing field polarity, 2) a negative ion region at the side of the opposing field polarity, and, 3) a neutral atom region in the middle between the separated ions' region. The neutral atom region constitutes the formed Si capacitance as it acts as an “atomic layer dielectric” (See FIG. 5B).

Dielectric Layer 120 Parameters—Table-1 outlines the salient parameters of several candidate materials for the dielectric layer 120 design parameters.

TABLE-1

| | Dielectric Layer Material | | |
|---|---|---|---|
| | Silicon | Silicon | Gallium |
| | Oxide | Nitride | Nitride |
| Properties | SiO₂ | Si₃N₄ | GaN |
| Dielectric Constant ε | 3.9 | 7.5 | 9 |
| Bandgap (eV) | 9 | 5 | 3.4 |
| Breakdown Voltage (V/nm) | 2.7 | 25 | Higher |
| Thickness at 100 v d (nm) | 37 | 4 | Higher |
| Capacitance Factor (ε/d) | 0.1 × 10⁹ | 1.875 × 10⁹ | Higher |

The relevance of the energy bandgap parameter for the dielectric layer 120 is that it should be greater than the energy of the indirect bandgap of the Si-Core layer 110 E_{g}=1.12 eV. The reason for this design consideration is the dielectric layer 120 should not absorb and become ionized by the photo-excitation light generated by LEDs 160 that are used to photo-ionize the Si-Core layer 110. The relevance of the breakdown potential parameter of the dielectric layer 120 is that it sets forth the applied field potential limit at the selected thickness for the dielectric layer 120, thus defining the upper limit of the stand-off field potential and its Si-Core layer 110 ionization and ion separation capabilities. For example, for a selected thickness of the dielectric layer 120, selecting silicon nitride (Si₃N₄) enables the stand-off potential to reach 10 times the value of silicon oxide (SiO₂) before breakdown condition occurs.

Another important factor to consider in selecting the dielectric layer 120 material minimum thickness besides the breakdown potential is material leakage at the target applied field potential. The leakage factor depends upon the crystalline properties of the selected dielectric material. As such, using monocrystalline dielectric material becomes more critical as the dielectric material thickness is reduced to increase its capacitance. The capacitance factor (dielectric constant/thickness) is the culmination of the dielectric layer 120 design parameters discussed in that it is a single parameter that can be maximized while accommodating the target applied field potential without reaching breakdown condition. Given the Si-Core layer 110 properties, and the dielectric layer 120 parameters of several candidate materials, the QPEC 100 design tradeoff examples discussed below assume the use of SisN4 material for the dielectric layer 120 since this material satisfies that design selection criteria outlined above with ample margin.

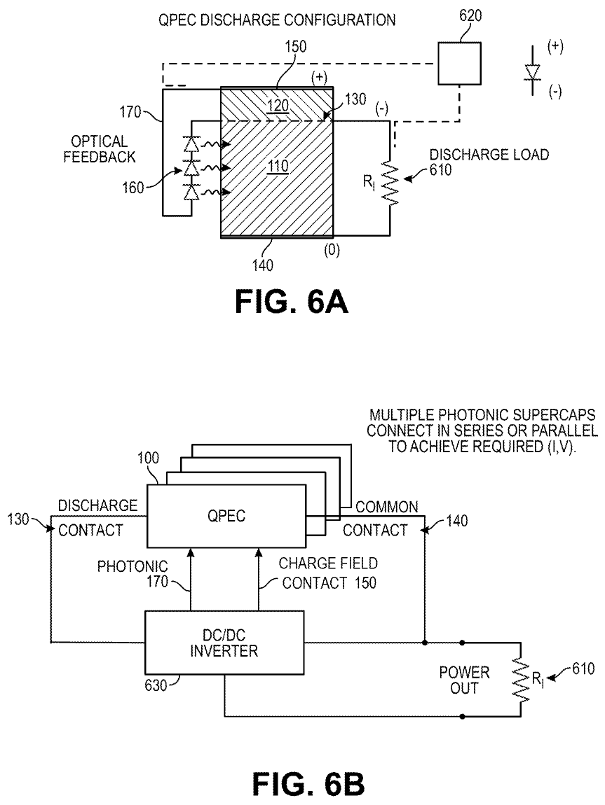

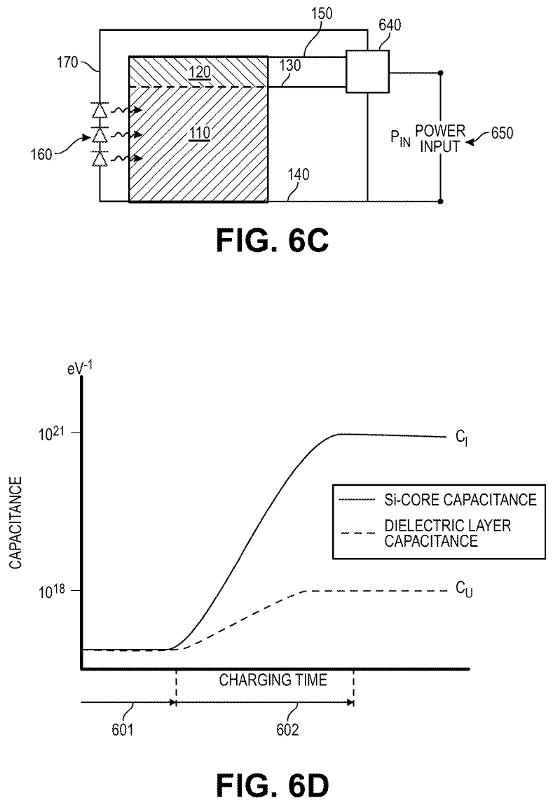

QPEC 100 Charge and Discharge Methods—FIG. 6A illustrates one embodiment of the QPEC 100 discharge configuration. In this QPEC 100 discharge configuration, a discharge load Rₗ 510 is connected between the common contact layer 140 and the contact layer 130 to extract (or discharge) the electrons stored in the Si-Core layer 110. Simultaneously the photo-ionization LEDs 160 are connected between the common contact layer 140 and the field contact layer 140 to discharge the energy stored in dielectric layer 120 and convert that energy into photoexcitation of the Si-Core layer 110.

A discharge control circuit 520 that senses the discharge current flow from the contact layer 130 to the load Rₗ 510 and the current flow from the contact layer 130 to the photo-excitation LEDs 160 regulates these two discharge current components to maintain energy balance between the Si-Core layer 110 and the dielectric layer 120. As electrons are discharged (or extracted) from the Si-Core layer 110 by the discharge (operational) load, or resistance, Rₗ 510, the excess stand-off electric field transposed by the dielectric layer 120 above the described 4-Fields' balance point is used to optically pump (or inject) more electrons into the Si-Core layer 110.

The excited electrons that are optically pumped into Si-Core layer 110 go through the quantum avalanche ionization process explained earlier to generate additional excited electrons to maintain the 4-Fields balance during the discharge process. The discharge current components allocated to the operational load RI 510 and to the photo-excitation LEDs 160 (optical pumping discharge feedback) are selected (controlled by the discharge circuit) such that the 4-Fields' balance and its associated stored energy balance are maintained as electrons are being extracted by the operational load Rₗ 510 from the Si-Core layer 110 through the discharge contact layer 130.

FIG. 6B illustrates a further embodiment of a QPEC 100 discharge configuration. In this discharge configuration, the QPEC 100 has three contacts, namely, the contact layer 130, the common contact layer 140 and the field contact layer 150. These contact layers are connected to an inverter 530 that regulates the discharge current from the contact layer 130 and the field contact layer 150, then inverts and combines the two extraction potentials into the extraction potential required by the operational load Rₗ 510.

As in the prior discharge configuration embodiment, the inverter 530 of the QPEC discharge configuration illustrated in FIG. 6B regulates the current drawn from the Si-Core layer 110 through the contact layer 130 and the current coupled into the field contact layer 150 to discharge dielectric layer 120 such that the values of these two discharge current components maintains the energy balance between Si-Core layer 110 and dielectric layer 120.

Again, with reference to FIG. 6B, the charged dielectric capacitance sustains the electric field, thus the charge separation of the Si-Core layer 110 of the QPEC 100 after the self-quenching charge threshold is reached. When charge carriers are extracted through the contact layer 130, both capacitances (mono—Si and dielectric) are discharged.

With respect to regulating the QPEC 100 discharge, during discharge, a feedback charge loop is turned on. The photo-ionizer is energized or turned on by feedback. Only the desired portion of energy is output to the load while the remainder of the extracted energy is fed back to recharge the mono—Si and dielectric capacitance. The discharge operates at the maximum energy output point for achieving the highest extraction efficiency, with excess energy beyond what is demanded by the load being fed back to recharge the capacitances. Connecting multiple photonic QPECs in series attains an ionization electric field level that makes the feedback regulator more efficient. The DC/DC inverter 530 controls the photonic QPEC 100 charge and discharge processes. In the charge cycle, it divides the charge power between the photo and field ionizers. In the discharge cycle, it regulates energy discharge rate and discharges at a required load rate.

FIG.6C illustrates an embodiment of the QPEC 100 charge configuration. In this QPEC 100 charge configuration, a charge power input Pin 650 is connected to a charge circuit (charger) 640 having four charge outputs provided to the QPEC 100 common contact layer 140, contact layer 130, field contact layer 150, photo-ionizer LEDs 160, and contact layer 170. In the initial stage of the charge process the target field potential generated by the charger 640 is connected to the field contact layer 150 and simultaneously to the photo-ionizer LEDs' 160 contact layer 170. To kick-start the coupled field transposition by the dielectric layer 120, a negative potential in the range of the Si-Core layer 110 chemical potential (˜3.4 V) is connected to the QPEC 100 contact layer 130. Supplying a charge potential through the contact layer 130 together with the field potential supplied through the field contact layer 150 expedites the dipolar polarization of the dielectric layer 120.

As the dielectric layer 120 becomes increasingly polarized during the initial stage of the charge process, the electric field that is coupled through the field contact layer 150 is transposed to the interface between the dielectric layer 120 and the Si-Core layer 110 to initiate the Si-Core layer 110 ionization process by the coupled field. The initial charge stage lasts until the dielectric layer 120 is sufficiently polarized to initiate the Si-Core layer 110 ionization process by the transposed coupled field. The indication of reaching the end of the initial charge stage is an increased current draw through the field contact layer 150 that substantiates the energy transferred from the coupled field to ionize the Si-Core layer 110.

When the initial charge stage is reached, the potential supply to the contact layer 130 is disconnected as the ionized Si-Core layer 110 negative ions accumulate near the dielectric layer interface 120 and their potential extends the dielectric layer 120 dipolar polarization further. As the combined ionization effects of the coupled light from the LEDs 160 and the coupled and transposed electric field systematically makes the Si-Core layer 110 reach the inversion state, the QPEC 100 reaches fully charged state.

FIG.6D illustrates the typical charge timeline of the QPEC 100. When the QPEC 100 reaches the fully charged state (inversion state), the charge storage capacitance of the Si-Core layer 110 is orders of magnitude higher than the charge storage capacitance of the dielectric layer 120. However, the potential of the charge stored in dielectric layer 120 is much higher than the potential of the charge stored in the Si-Core layer 110. The opposing difference in the magnitude of the stored charges and their potential in the Si-Core layer 110 and the dielectric layer 120 accounts for the energy stored in these two layers of QPEC 100 being equal.

As illustrated in FIG. 6D, during a first charging period 601, two dielectric layers are charged by a set of outer contacts as a single capacitor with a composite dielectric constant. During the second charging period 602 following the first charging period 601, the Si-Core layer 110 dielectric is photo-ionized, then further ionized by the two outer contacts' field. The ionized SI-Core layer 110 charges form a split, ionic capacitor, making the two dielectrics separate into two separate capacitors sharing the negative Si-Core layer 110 ions. The ionized Si-Core layer 110 forms an ionic super capacitance that is orders of magnitude larger than the upper dielectric capacitance.

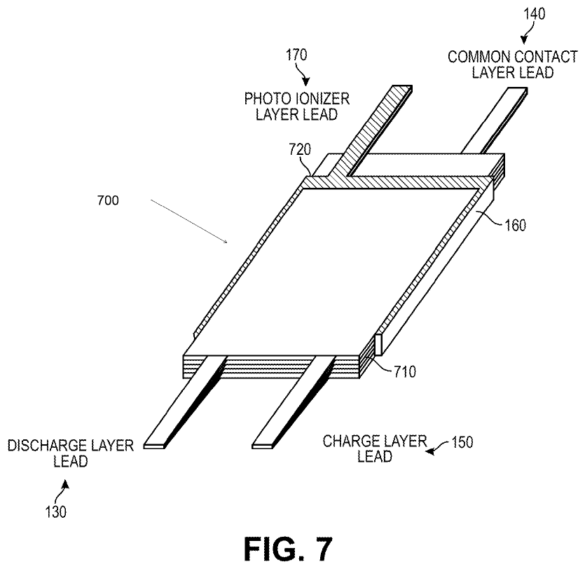

QPEC 100 Packaging Methods—FIG. 7 illustrates an exemplar packaging configuration 700 of the QPEC 100. The QPEC 100 can be manufactured in standard semiconductor wafer sizes, for example, 10 cm, 15 cm, 20 cm, 25 cm or 30 cm in diameter. The manufactured QPEC 100 wafers are then diced into cell sections having the approximate dimensions of the QPEC package (or module). The thickness of the diced section is determined by the thickness of the Si-Core layer 110, for example, in the range of ˜200 to 300 microns. The diced QPEC sections are then stacked with the adjacent cell's surfaces and eutectic-bonded together while allowing a contact metal to extend beyond the diced QPEC 100 cell section dimensions. The extended metal contacts of the stacked and bonded QPEC 100 cell sections are connected to create the four contact leads of the QPEC module illustrated in FIG. 7, i.e., the contact layer 130 lead, the common contact layer 140 lead, the field contact layer 150 lead and the LEDs 160 contact 170 lead. The isometric illustration of FIG. 7 shows the multiple QPEC 100 cell sections stack 710 and the LEDs 160 optically coupled to the edge of the QPEC 100 cell sections stack 710. With the illustrated QPEC 100 packaging configuration 700, the photoexcitation LEDs are assembled separately on a flex substrate 720 which is first bonded onto one surface of the QPEC 100 cell sections stack 710 then optically bonded to the edge of the QPEC 100 cell sections stack 710.

The total final thickness of the QPEC 100 module 700 depends on the number of QPEC 100 stacked sections comprising the module and typically depends on the target application. For example, for wearable and mobile electronics applications where both weight and volumetric displacement are paramount, a 1 mm or 2 mm thick QPEC module 700 can be packaged using stacks of 5 to 10 QPEC 100 200-micron thick sections.

Based on the QPEC 100 design example discussed below, the energy density metric of a 200-micron thick QPEC 100 is in the range 146 mW.Hr.cm² of its surface area. Based on this energy density metric, a 1 mm thick QPEC module 700 comprising a stack of five 200-microns thick QPEC 100 sections and having 10 cm² of surface area supplies approximately 7.3 WHr of energy, which is a substantially improvement over currently available state-of-the-art batteries, which in turn enables a robust energy supply for phones and laptop PCs to permit use for extended time periods and enables wearable electronics having extensive processing capabilities, yet that are light in weight and small in volume.

QPEC 100 Design Methods—The most salient design aspect of the QPEC 100 is the equality of the energy stored in the Si-Core layer 110 and the dielectric layer 120 capacitances. Using this stored energy equality property plus the inversion state property of the QPEC 100 avalanche process of exciting nearly half of the Si-Core layer 110 atoms when the inversion (fully charged) state is reached, the energy storage capacitance of the Si-Core layer 110, designated as Cₗ, is determined. The Si-Core layer 110 and the dielectric layer 120 stored energy equality property is used to determine the thickness of the dielectric layer 120, designated as du, and coupled electric field potential, designated V.

Using the determined coupled electric field potential V, the chemical potential of the Si ions that are stored in Si-Core layer 110, designated v, and the ratio of dielectric layer 120 dielectric constant to the Si-Core layer 110 dielectric constant, designated as (αᵤ/αₗ), the ratio of the dielectric layer 120 thickness to the Si-Core ions separation 115 width, designated as (dᵤ/dₗ), is determined. With these design parameters of the QPEC 100 determined, the combined energy stored in the Si-Core layer 110 and the dielectric layer 120 determines the total energy stored in the QPEC 100.

Using the disclosed QPEC 100 design method, the Si-Core layer 110 ions separation 115 width dₗ, versus the coupled electric field potential V for a range of the dielectric layer 120 thickness dᵤ is tabulated in Table-2.

TABLE-2

| | | dₗ | | | |
|---|---|---|---|---|---|
| V | Cₗ/Cᵤ | dᵤ = 20 nm | dᵤ = 30 nm | dᵤ = 40 nm | dᵤ = 50 nm |
| 25 v | 69.77 | 455 pm | 682 pm | 909 pm | 1.14 pm |
| 27.6 v | 83.13 | 381 pm | 572 pm | 763 pm | 954 pm |
| 30 v | 96.50 | 329 pm | 493 pm | 657 pm | 822 pm |
| 34.6 v | 124.91 | 254 pm | 381 pm | 508 pm | 635 pm |
| 35 v | 127.56 | 249 pm | 378 pm | 498 pm | 623 pm |
| 37.4 v | 144. | 220 pm | 330 pm | 441 pm | 551 pm |
| 40 v | 162.94 | | 292 pm | 390 pm | 487 pm |
| 40.5 v | 166.71 | | 286 pm | 381 pm | 476 pm |
| 45 v | 202.64 | | 235 pm | 313 pm | 391 pm |
| 45.6 v | 207.7 | | 229 pm | 305 pm | 381 pm |
| 46.6 v | 216.26 | | 220 pm | 293 pm | 367 pm |
| 50 v | 246.67 | | | 257 pm | 321 pm |
| 54.3 v | 288.0 | | | 220 pm | 275 pm |
| 55 v | 295.03 | | | | 269 pm |
| 60 v | 347.71 | | | | 228 pm |
| 61.1 v | 359.88 | | | | 220 pm |

In this QPEC 100 design example, the Si-Core layer 110 thickness is selected at 200 microns and the silicon nitride (Si₃N₄) material is selected for the dielectric layer 120. With these selected design parameters, the dielectric constant of the dielectric layer is 120αᵤ=7.5, and the dielectric constant of the Si-Core layer 110 material is αₗ=11.9, and their ratio is (αᵤ/αₗ)=0.63. The dielectric layer 120 material should be selected to enable the highest possible value of the dielectric constants' ratio (αᵤ/αₗ). With these selections of the QPEC design parameters, as illustrated in Table-2, for the coupled electric field potential V ranging from 25 v to 70 v, the Si-Core layer 110 separation 115 width di is from one to five Si atoms when the dielectric layer 120 thickness dᵤ is selected in the range from about 20 nm to about 50 nm.

Within the range of the QPEC 100 design parameters, the energy stored in dielectric layer 120, which also equals the energy stored in Si-Core layer 110, is presented in Table-3 when the Si-Core layer 110 thickness is 200-microns, the Si-Core layer 110 ions' separation 115 width dₗ is two Si atoms, i.e., dₗ=381 nm and the dielectric layer 120 thickness du ranges from 20 nm to 50 nm.

TABLE-3

| | | Cᵤ (10¹⁸ e⁻ v⁻¹ cm⁻²) | | | |
|---|---|---|---|---|---|
| V | Cₗ/Cᵤ | dᵤ = 20 nm | dᵤ = 30 nm | dᵤ = 40 nm | dᵤ = 50 nm |
| 27.6 v | 83.13 | 3.538 | | | |
| 34.6 v | 124.91 | | 2.357 | | |
| 40.5 v | 162.94 | | | 1.743 | |
| 45.6 v | 166.71 | | | | 1.1418 |

Dₗ = 381 nm, 2-atom monolayer
Cₗ = 0.294 × 10²¹ e⁻ v⁻¹ cm⁻²
Si₃N₄ Dielectric Layer
Eᵤ = Eₗ = 73.19 mW Hr cm⁻²
Total Energy = Eᵤ = Eₗ = 146.38 mW Hr cm⁻²

As illustrated in Table-3, the energy stored in dielectric layer 120 is in the range of 73.19 mW.Hr.cm² of surface area of the QPEC 100. With the energy equality property of QPEC 100, the design example presented in Table-3 indicates that using the selected QPEC 100 design parameters, the QPEC 100 stored energy is in the range 146 mW.Hr.cm² of surface area of QPEC 100.

Extrapolating the stored energy per square centimeter of surface area of QPEC 100 while considering the selected Si-Core layer 110 thickness of 200 microns, based on this design example, the QPEC 100 volumetric density is 7.3 KWHr/L. In considering the density of the Si-Core layer 110 material of 2.238 g/cm², based on this design example, the QPEC 100 gravimetric density is 3.136 KWHr/Kg.

Given that the most popular energy cell, namely Li-lon, has a volumetric energy density range from 0.25 to 0.7 KWHr/L, the QPEC 100 volumetric energy density outperforms Li-lon cells by a factor ranging from 10x to 29x. Given that gravimetric density energy density of Li-lon cells ranges from 0.1 to 0.265 KWHr/Kg, based on this design example, the QPEC 100 gravimetric energy density easily outperforms Li-lon cells by a factor ranging from 12x to 31x.

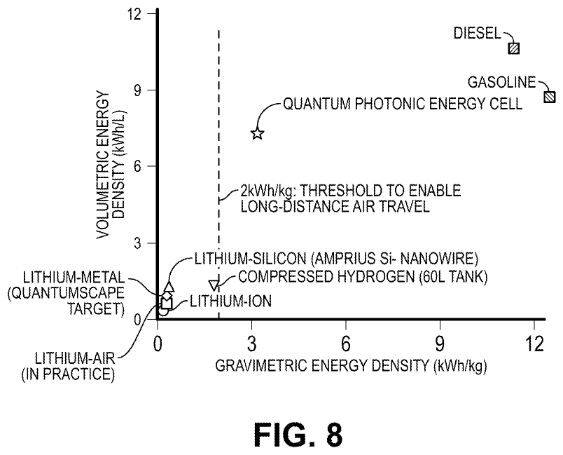

Energy density comparison-Using the presented QPEC 100 stored energy of the foregoing design example, FIG. 8 presents a comparison of the QPEC volumetric and gravimetric energy densities with that of the most popular batteries currently available and predicted to be available in the future.

As can be seen from FIG. 8, the QPEC energy density is multiple times higher than the energy density of popular batteries, thus substantially closing the energy density gap between popular batteries and fossil fuels and enabling a more effective electric energy storage for a wide range of applications, including applications that are highly dependent on fossil fuel energy density, such as aircraft.

As illustrated in FIG. 8, the QPEC 100 gravimetric energy density of 3.136 KWHr/Kg exceeds the threshold of 2 KWHr/Kg to enable long-distance air travel, thus the QPEC 100 is a viable energy storage cell to enable electrical aircraft and electrical long-distance air travel.

Those skilled in the art will readily appreciate that various modifications and changes can be applied to the embodiments of the invention without departing from its scope defined in and by the appended claims. It should be appreciated that the foregoing examples of the invention are illustrative only, and that the invention can be embodied in other specific forms without departing from the spirit or essential characteristics thereof. The disclosed embodiments, therefore, should not be considered restrictive in any sense. The scope of the invention is indicated by the appended claims, rather than the preceding description, and all variations which fall within the meaning and range of equivalents thereof are intended to be embraced therein.

What is claimed:

1. A multilayer solid state energy storage device comprising:
A silicon core layer;
a dielectric layer comprising an electrically conductive structure defining a contact layer disposed on the Si core layer,
at least one LED disposed on a surface of the device configured to ionize the Si core layer using a predetermined frequency of light; and;
the contact layer interposed between the dielectric layer and the Si core layer and configured to extract charge carriers from the device when the device is a charged inversion state.

2. An energy storage cell comprising:
a core layer comprising monocrystalline silicon having a thickness between approximately 100 and 300 microns;
a dielectric layer adjacent to the core layer, the dielectric layer having a dielectric constant less than that of the core layer and a bandgap energy greater than that of the core layer;
a discharge contact layer interposed at an interface between the core layer and the dielectric layer and configured to extract charge carriers from the core layer;
a charge contact layer adjacent to the dielectric layer and configured to apply an electric field across the dielectric and core layers;
a common contact layer adjacent to a surface of the core layer opposing the dielectric layer;
a plurality of photo-ionizing light emitting diodes (LEDs) optically coupled to at least one lateral surface of the core layer and configured to emit light with photon energy greater than twice the indirect bandgap of silicon; and;
an LED contact layer electrically coupled to the plurality of LEDs and configured to supply
a drive potential in reference to the common contact layer,
wherein the energy storage cell is configured to store electrical energy through combined photonic and electric field-induced avalanche ionization of the silicon core layer.

3. The energy storage cell of claim 2 wherein the discharge contact layer comprises a mesh of metal rails and metal fingers or graphene fingers and carbon nanotube rails that are diffused into the silicon core layer to a depth of about 20 to 50 microns.

4. The energy storage cell of claim 2 wherein the dielectric layer is composed of silicon nitride deposited via atomic layer deposition or molecular beam epitaxy.

5. The energy storage cell of claim 2 wherein the core layer achieves an inversion state characterized by separation of positive and negative silicon ions by a monolayer of un-ionized silicon atoms.

6. A method of charging an energy storage cell comprising a silicon core layer, a dielectric layer, a discharge contact layer, a charge contact layer, a common contact layer, and photo-ionizing LEDs optically coupled to the core layer, the method comprising:
applying a charge electric potential across the charge contact layer and the common contact layer to generate an electric field across the dielectric and core layers;
activating the photo-ionizing LEDs to emit light having photon energy greater than 2.24 eV to photo-ionize the silicon core layer;
accelerating the photo-excited charge carriers within the silicon core layer by the electric field to induce an avalanche ionization; and;
storing electrical energy in the form of ion polarization within the silicon core layer and dipolar polarization within the dielectric layer.

7. The method of claim 6 wherein the dielectric layer transposes the electric field from the charge contact layer to the interface between the dielectric layer and the silicon core layer without allowing free charge carrier interaction.

8. The method of claim 6 wherein the avalanche ionization continues until an inversion state is reached wherein approximately half the silicon atoms in the core layer are ionized.

9. The method of claim 6 further comprising terminating the potential to the discharge contact layer after the dielectric layer becomes sufficiently polarized to transpose the electric field.
